(19) United States
(12) Patent Application Publication
(10) Pub. No.: US 2025/0333580 A1
(43) Pub. Date: Oct. 30, 2025

(54) RESIN COMPOSITION AND PRODUCTS THEREOF

(71) Applicant: ELITE ELECTRONIC MATERIAL (ZHONGSHAN) CO., LTD., Zhongshan City (CN)

(72) Inventors: Zhilong HU, Zhongshan City (CN); Changyuan LI, Zhongshan City (CN); Hezong ZHANG, Zhongshan City (CN); Hongxia PENG, Zhongshan City (CN)

(21) Appl. No.: 18/752,173

(22) Filed: Jun. 24, 2024

(30) Foreign Application Priority Data
Apr. 28, 2024 (CN) 202410525067.0

(51) Int. Cl. C08K 5/50; C08L 79/08

(52) U.S. Cl. CPC C08K 5/50; C08L 79/08; C08L 2201/50

(57) ABSTRACT

Disclosed is a resin composition, including 100 parts by weight of maleimide resin and 0.3 parts by weight to 10.0 parts by weight of organophosphine compound having a structure shown in Formula (1), wherein —R— includes a substituted or unsubstituted phenylene group, biphenylene group, or naphthylene group. Also disclosed are a use of the resin composition in preparing a product, and at least a portion of the product made from the resin composition. The product includes a prepreg, a resin film, a laminate, a printed circuit board, or a cured insulator.

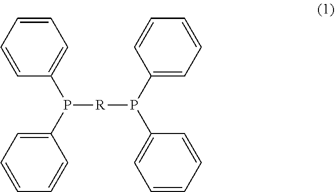

### CROSS-REFERENCE TO RELATED APPLICATIONS

This application claims the priority to Chinese Patent Application No. 202410525067.0, filed to China National Intellectual Property Administration on Apr. 28, 2024, which is incorporated by reference herein in its entirety.

### FIELD

The present application relates to the field of compositions, and particularly to a resin composition and products thereof.

### BACKGROUND

In recent years, electronic technology has been developing towards higher integration, lower power consumption, and higher performance, thus placing higher demands on high-performance electronic materials. Laminate materials with a higher glass transition temperature (Tg) or a lower ratio of thermal expansion have been an important development direction for printed circuit boards in order to ensure the stability and reliability of electronic materials. A high glass transition temperature may ensure that the printed circuit board can maintain stable electrical characteristics in a high temperature environment, and a low ratio of thermal expansion may ensure that the printed circuit board can maintain a small dimensional change when the temperature changes, which may prevent connection failure between elements. Therefore, how to develop a suitable high-performance laminate material with a high glass transition temperature and a low ratio of thermal expansion is a goal of active efforts in the industry at present.

In addition, while ensuring that a material may achieve high glass transition temperature and low ratio of thermal expansion characteristics, how to balance the flow characteristics of the material in a semi-cured state and normal appearance in a cured state is also a problem to be solved by the industry.

### SUMMARY

In view of the problems encountered in the related art, particular the inability of existing materials to meet requirements of one or more of the above-mentioned characteristics, a primary object of the present application is to provide a resin composition, as well as products made from the resin composition, that can overcome at least one of the above-mentioned technical problems.

In one aspect, the present application provides a resin composition, comprising 100 parts by weight of a maleimide resin and 0.3 parts by weight to 10.0 parts by weight of an organophosphine compound, wherein the organophosphine compound has a structure shown in Formula (1),

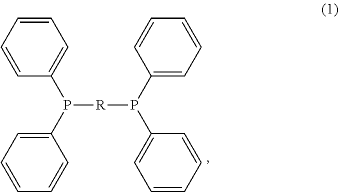

wherein —R— comprises a substituted or unsubstituted phenylene group, biphenylene group or naphthylene group.

In one aspect, the present application provides a use of the resin composition in preparing a product comprising a prepreg, a resin film, a laminate, a printed circuit board, or a cured insulator.

In one aspect, the present application provides a product, comprising a prepreg, a resin film, a laminate, a printed circuit board, or a cured insulator, wherein at least a portion of the product is made from the resin composition.

The resin composition or the products thereof provided by some embodiments of the present application may be improved in one or more aspects of glass transition temperature, ratio of thermal expansion, inner resin flow, resin flow, laminate edge stripe, or the like.

### BRIEF DESCRIPTION OF THE DRAWINGS

FIG. 1 is a figure showing the appearance of a copper-free laminate with a distribution of dendritic stripes (a.k.a. laminate edge stripe).

FIG. 2 is a figure showing the appearance of a copper-free laminate without a distribution of dendritic stripes (a.k.a. laminate edge stripe).

### DETAILED DESCRIPTION

In order to further elaborate the technical means and functions adopted by the present application to achieve the intended purpose, the specific embodiments, structures, features, and functions of the present application are described in detail as follows with reference to the accompanying drawings and preferred embodiments.

### Terms and Definitions

The terms used herein (including technical and scientific terms) have the same meaning as those generally understood by those skilled in the art. If otherwise specified, the terms defined herein shall prevail.

Singular terms used herein refer to one or more. For instance, “an element” or “one element” refer to one or more elements. “A plurality of” used herein refers to at least two.

“Include”, “comprise”, “have” and “contain” used herein are all open-ended transitional phrases (i.e., they may also include other unlisted elements). “Consist of” and “composed of” used herein this article are all close-ended transitional phrases.

Numerical ranges used herein include all possible subranges and all individual numbers (including fractions and integers) within said ranges.

“About” used herein refers to approximately, in the range of about or around. When used in combination with a value range, the term “about” modifies the range by extending the limit above or below the value provided. In general, the term “about” is used herein to give a value plus or minus 10% from the value provided. For instance, “about 50%” refers to a range of 45% to 55%. It should also be understood that all the integers and fractions are defined by the term “about”. Numerical values used herein include all numerical ranges that are the same as the numerical values after rounding to the nearest significant digit.

It should be understood that each member of the Markush group can be used to describe the present invention individually and/or in combination. “Or a combination thereof” used herein is “or any combination thereof”.

The compound of the present application may have an asymmetric center or chiral center, and exist in the form of different stereoisomers. It should be regarded that all stereoisomers of the compound of the present application include a diastereomer, an enantiomer, an atropisomer, and a mixture thereof, such as a racemic mixture, which form part of the present application, but the present invention is not limited thereto.

The “polymer” used herein refers to a product formed by the polymerization of a monomer. The polymer may include homopolymer, copolymer, prepolymer, or the like, but the present invention is not limited thereto.

The “homopolymer” used herein refers to a chemical substance formed by polymerization, addition polymerization, and condensation polymerization of a single compound. The “copolymer” refers to a chemical substance formed by polymerization, addition polymerization, or condensation polymerization of two or more compounds, including random copolymer (having a structure such as -AABABBBAAABBA-), alternating copolymer (having a structure such as -ABABABAB—), graft copolymer (having a structure such as -AA(A-BBBB)AA(A-BBBB)AAA-), block copolymer (having a structure such as -AAAAA-BBBBBB-AAAAA-), and the like.

The “prepolymer” used herein refers to a lower molecular weight polymer having a molecular weight between that of the monomer and the final polymer, and the prepolymer contains reactive functional groups that may be further polymerized to obtain a fully crosslinked or hardened higher molecular weight product.

The polymer includes oligomer, but the present invention is not limited thereto. The oligomer, a.k.a. low molecular polymer, consists of 2 to 20 repeating units, usually 2 to 5 repeating units.

The “modifier” used herein includes a product after modification of the reactive functional group of each resin, a product after prepolymerization of each resin with other resins, a product after crosslinking of each resin with other resins, a product after homopolymerization of each resin, a product after copolymerization of each resin with other resins, and the like. For instance, modification may be to replace the original hydroxyl into vinyl through a chemical reaction, or to obtain a hydroxyl-terminated through a chemical reaction between the original vinyl-terminated and aminophenol-terminated, but the present invention is not limited thereto.

Various alkyl, various alkenyl, and various hydrocarbyl used herein are meant to include the various isomers thereof. For instance, the “propyl” used herein includes n-propyl and isopropyl.

The term “resin” used herein may include forms of a monomer, a polymer thereof, a combination of monomers, a combination of polymers thereof, or a combination of monomers and polymers thereof, or the like, but the present invention is not limited thereto. For instance, “maleimide resin” herein includes at least a maleimide monomer (a maleimide small molecule compound), a maleimide polymer, a combination of maleimide monomers, a combination of maleimide polymers, and a combination of the maleimide monomer and the maleimide polymer.

The “polyfunctional” refers to that the referred molecule (particularly a monomer of a polymer) includes two or more referred functional groups. For instance, “polyfunctional maleimide” includes two or more maleimide functional groups; “polyfunctional amine” includes two or more amino groups; “polyfunctional phenol” includes two or more phenolic hydroxyl groups.

Parts by weight used herein represent represents a number of parts of weight, which may be any unit of weight, such as kilograms, grams, and pounds, but the present invention is not limited thereto. For instance, 100 parts by weight of the maleimide resin may represent 100 kilograms of the maleimide resin or 100 pounds of the maleimide resin.

### EMBODIMENTS OF THE PRESENT APPLICATION

In one aspect, the present application provides a resin composition, comprising 100 parts by weight of a maleimide resin and 0.3 parts by weight to 10.0 parts by weight of an organophosphine compound. The organophosphine compound has a structure shown in Formula (1), wherein —R— is a divalent aryl group.

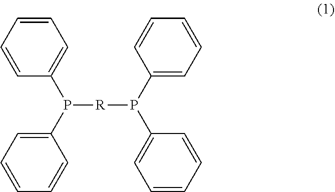

In some exemplary examples, the divalent aryl group may comprise a substituted or unsubstituted phenylene group, biphenylene group or naphthylene group. Particularly, the divalent aryl group may be the unsubstituted phenylene group, biphenylene group or naphthylene group, but the present invention is not limited thereto. The phenylene group may be 1,2-phenylene, 1,3-phenylene, or 1,4-phenylene, particularly 1,2-phenylene. The biphenylene group may be 2,2′-biphenylene, 2,3′-biphenylene, 2,4′-biphenylene, 3,3′-biphenylene, 3,4′-biphenylene, or 4,4′-biphenylene, particularly 2,2′-biphenylene. The naphthylene group may be 1,2-naphthylene, 1,3-naphthylene, 1,4-naphthylene, 1,5-naphthylene, 1,6-naphthylene, 1,7-naphthylene, 1,8-naphthylene, 2,3-naphthylene, 2,6-naphthylene, or 2,7-naphthylene, particularly 1,8-naphthylene, but the present invention is not limited thereto.

In some exemplary examples, the organophosphine compound may contain a substituent group on a benzene ring of the diphenylphosphanyl.

In some exemplary examples, the aforementioned substituent group on the benzene ring of the diphenylphosphanyl or the substituent group on the divalent aryl group may independently be a monovalent alkyl, alkoxy, alkylamino, alkylthio, aryl, benzyl, aryloxy or benzyloxy having 1 to 13 carbon atoms, for instance may be methyl, ethyl, propyl, butyl, tert-butyl, pentyl, hexyl, heptyl, octyl, nonyl, decyl, phenyl, benzyl, methoxy, ethoxy, propoxy, butoxy, phenoxy, benzyloxy, dimethylamino, diethylamino, methylthio or ethylthio, but the present invention is not limited thereto. In some exemplary examples, the aforementioned substituent group on the benzene ring of the diphenylphosphanyl or the substituent group on the divalent aryl group may independently be a monovalent alkyl, alkoxy or alkylamino having 1 to 4 carbon atoms, or be a phenyl or benzyl.

In some exemplary examples, the organophosphine compound comprises 1,2-bis(diphenylphosphanyl)benzene, 2,2′-bis(diphenylphosphanyl)biphenyl, 1,8-bis(diphenylphosphanyl)naphthalene, or a combination thereof. The structures of 1,2-bis(diphenylphosphanyl)benzene, 2,2′-bis(diphenylphosphanyl)biphenyl, and 1,8-bis(diphenylphosphanyl)naphthalene are shown in Formula (2), Formula (3), and Formula (4), respectively.

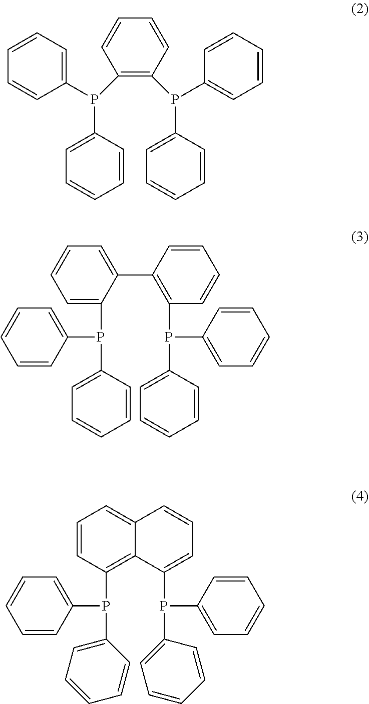 [SMILES: c1ccc(P(c2ccccc2)c2ccccc2P(c2ccccc2)c2ccccc2)cc1 ; c1ccc(P(c2ccccc2)c2ccccc2-c2ccccc2P(c2ccccc2)c2ccccc2)cc1 ; c1ccc(P(c2ccccc2)c2cccc3cccc(P(c4ccccc4)c4ccccc4)c23)cc1]

In some exemplary examples, the maleimide resin may comprise a compound or a mixture having more than one maleimide functional group in a molecule. The maleimide resin employed by the present application may be any one or more maleimide resins for the manufacture of prepreg, resin film, laminate, printed circuit board, or cured insulator, but the present invention is not limited thereto.

Specific examples of the maleimide resin may comprise 4,4′-diphenylmethane bismaleimide, phenylmethane maleimide oligomer, biphenyl aralkyl bismaleimide, indane structure-containing bismaleimide, m-phenylene bismaleimide, bisphenol A diphenyl ether bismaleimide, 3,3′-dimethyl-5,5′-diethyl-4,4′-diphenylmethane bismaleimide, 4-methyl-1,3-phenylene bismaleimide, 1,6-bismaleimide-(2,2,4-trimethyl)hexane, 2,3-dimethylbenzene maleimide, 2,6-dimethylbenzene maleimide, N-phenylmaleimide, a maleimide resin containing an aliphatic long chain structure, or a combination thereof, but the present invention is not limited thereto.

In some exemplary examples, the maleimide resin may be any one or more maleimide resin prepolymers having more than one maleimide functional group in the molecule for the manufacture of prepreg, resin film, laminate, printed circuit board, or cured insulator. The maleimide resin may comprise a prepolymer of a diallyl compound and the maleimide resin, a prepolymer of polyfunctional amine and the maleimide resin, a prepolymer of an acidic phenol compound and the maleimide resin, or a combination thereof, but the present invention is not limited thereto.

In some exemplary examples, the maleimide resin may be a polyfunctional maleimide resin. The polyfunctional maleimide resin may comprise 4,4′-diphenylmethane bismaleimide, phenylmethane maleimide oligomer, biphenyl aralkyl bismaleimide, indane structure-containing bismaleimide, m-phenylene bismaleimide, bisphenol A diphenyl ether bismaleimide, 3,3′-dimethyl-5,5′-diethyl-4,4′-diphenylmethane bismaleimide, 4-methyl-1,3-phenylene bismaleimide, 1,6-bismaleimide-(2,2,4-trimethyl)hexane, a polyfunctional maleimide resin containing an aliphatic long chain structure, or a combination thereof, but the present invention is not limited thereto.

For instance, the maleimide resin may be a maleimide resin produced by Daiwa Kasei Co., Ltd under trade names of BMI-1000, BMI-1000H, BMI-1100, BMI-1100H, BMI-2000, BMI-2300, BMI-3000, BMI-3000H, BMI-4000H, BMI-5000, BMI-5100, BMI-7000, BMI-7000H, etc., a maleimide resin produced by K. I. Chemical Co., Ltd under trade names of BMI-70, BMI-80, etc., a maleimide resin produced by Nippon Kayaku Co., Ltd under the trade name of MIR-3000, etc., or a maleimide resin produced by DIC Co., Ltd under trade names of X9-470, NE-X-9470S, NE-X-9480, etc.

For instance, the maleimide resin containing an aliphatic long chain structure may be a maleimide resin produced by Designer Molecular Company under trade names of BMI-689, BMI-1400, BMI-1500, BMI-1700, BMI-2500, BMI-3000, BMI-5000, BMI-6000, etc. The maleimide resin containing an aliphatic long chain structure may have at least one maleimide functional group attached to a substituted or unsubstituted long chain aliphatic group. The long chain aliphatic group may be an aliphatic group having a carbon number of C₅ to C₅₀, such as C₁₀ to C₅₀, C₂₀ to C₅₀, C₃₀ to C₅₀, C₂₀ to C₄₀, or C₃₀ to C₄₀, but the present invention is not limited thereto.

For instance, examples of commercially available maleimide resins containing aliphatic long chain structures are as follows:

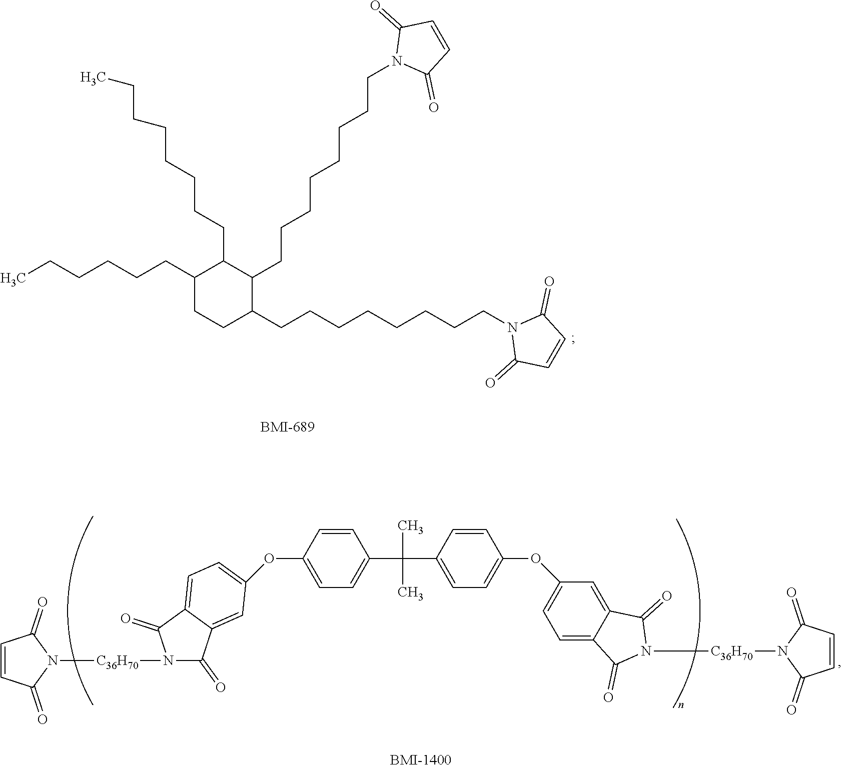

wherein n is 1-10;

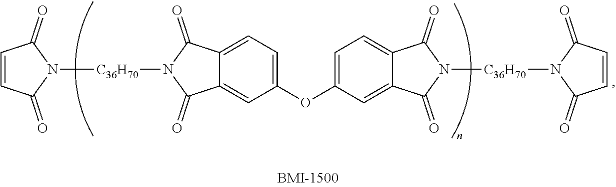

wherein n has an average value of 1.3;

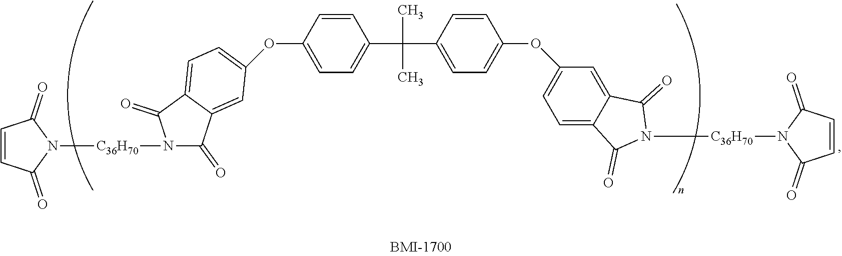

wherein n is 1-10;

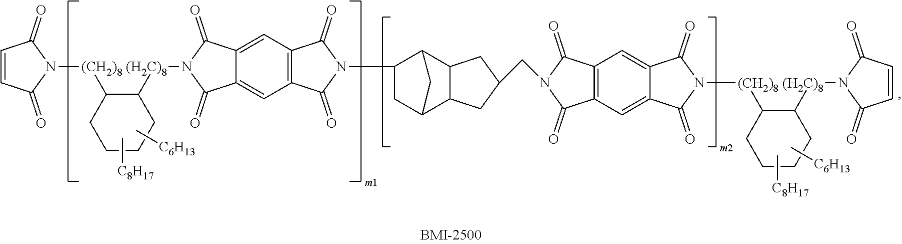

wherein m1 has an average value of 3, and m2 has an average value of 3;

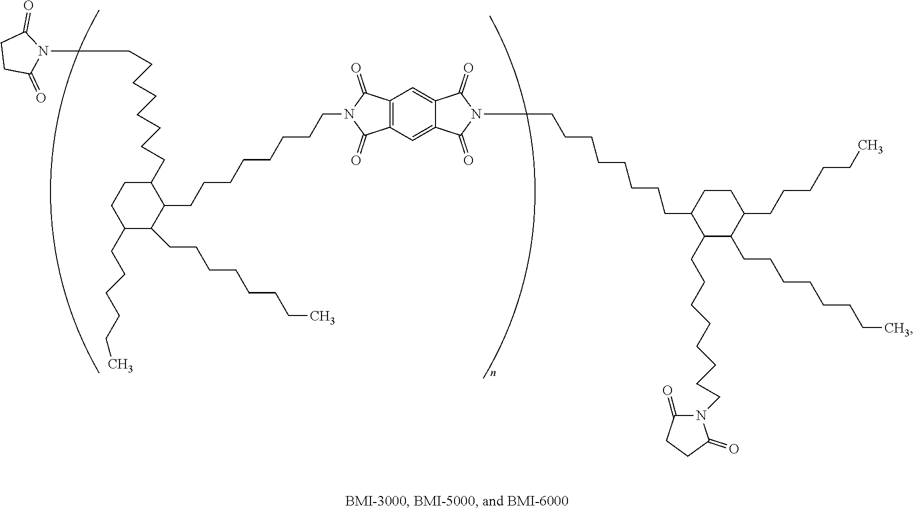

wherein n is 1-10.

In some exemplary examples, the resin composition may further comprise an epoxy resin. For instance, the epoxy resin may be various types of epoxy resins known in the art and may comprise, for instance, bisphenol A epoxy resin, bisphenol F epoxy resin, bisphenol S epoxy resin, bisphenol AD epoxy resin, novolac epoxy resin (such as a polyfunctional novolac epoxy resin), trifunctional epoxy resin, tetrafunctional epoxy resin, dicyclopentadiene (DCPD) epoxy resin, phosphorus-containing epoxy resin, p-xylene epoxy resin, naphthalene epoxy resin (such as a naphthol epoxy resin), benzofuran epoxy resin, isocyanate-modified epoxy resin, or a combination thereof, but the present invention is not limited thereto.

The novolac epoxy resin may be phenol novolac epoxy resin, bisphenol A novolac epoxy resin, bisphenol F novolac epoxy resin, biphenyl novolac epoxy resin, phenol benzaldehyde epoxy resin, phenol aralkyl novolac epoxy resin, o-cresol novolac epoxy resin, or a combination thereof.

The phosphorus-containing epoxy resin may be 9,10-dihydro-9-oxa-10-phosphaphenanthrene-10-oxide (DOPO) epoxy resin, DOPO-HQ epoxy resin, or a combination thereof. The aforementioned DOPO epoxy resin may be selected from one or more of a DOPO-containing phenolic novolac epoxy resin, DOPO-containing cresol novolac epoxy resin, and a DOPO-containing bisphenol A novolac epoxy resin. The aforementioned DOPO-HQ epoxy resin may be selected from at least one of a DOPO-HQ-containing phenolic novolac epoxy resin, DOPO-HQ-containing cresol novolac epoxy resin, and a DOPO-HQ-containing bisphenol A novolac epoxy resin.

In some exemplary examples, the epoxy resin may comprise biphenyl novolac epoxy resin, DCPD epoxy resin, o-cresol novolac epoxy resin, naphthol epoxy resin, or a combination thereof.

The amount of the epoxy resin is not particularly limited. In some exemplary examples, the resin composition may comprise 5 parts by weight to 30 parts by weight of the epoxy resin with respect to 100 parts by weight of the maleimide resin.

In some exemplary examples, the resin composition may further comprise a diallyl bisphenol resin. The diallyl bisphenol resin may comprise a compound shown in Formula (5) or Formula (6), or a combination thereof:

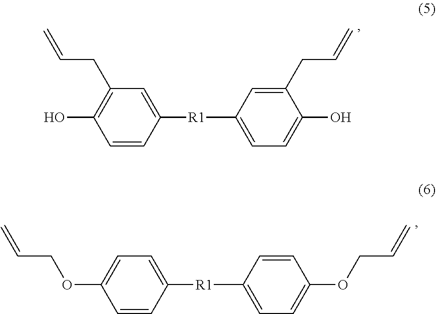

wherein R1 is —C(CH₃)₂—, —CH₂—, or —SO₂—.

In some exemplary examples, the diallyl bisphenol resin may comprise, diallyl bisphenol A, diallyl bisphenol F, diallyl bisphenol S, bisphenol A bisallyl ether, or a combination thereof, but the present invention is not limited thereto.

The amount of the diallyl bisphenol resin is not particularly limited. In some exemplary examples, the resin composition may comprise 5 parts by weight to 20 parts by weight of the diallyl bisphenol resin with respect to 100 parts by weight of the maleimide resin.

In some exemplary examples, the resin composition may further comprise at least one of polyolefin resin, maleimide triazine resin, small molecule vinyl-containing resin, small molecule vinyl-containing resin prepolymer, styrene maleic anhydride resin, phenol resin, benzoxazine resin, cyanate ester resin, polyester resin, polyamide resin, polyimide resin.

In some exemplary examples, the resin composition comprises polyolefin resin. The polyolefin resin may comprise unsaturated polyolefin resin, hydrogenated unsaturated polyolefin resin, or a combination thereof, but the present invention is not limited thereto. The unsaturated polyolefin resin may be any one or more polyolefin resins containing unsaturated carbon-carbon double bonds for the manufacture of prepreg, resin film, laminate, printed circuit board, or cured insulator. The unsaturated polyolefin resin may comprise at least one of styrene-butadiene-divinylbenzene terpolymer, ethylene-divinylbenzene-styrene polymer, maleic anhydride-added styrene-butadiene copolymer, maleic anhydride-added polybutadiene, styrene-butadiene-styrene block polymer, vinyl-polybutadiene-urethane oligomer, styrene-butadiene copolymer, styrene-isoprene copolymer, polybutadiene, ethylene propylene diene monomer, methylstyrene homopolymer, petroleum resin, cyclic olefin copolymer, or a combination thereof, but the present invention is not limited thereto.

The hydrogenated unsaturated polyolefin resin may be obtained by hydrogenating the unsaturated polyolefin resin. The hydrogenated unsaturated polyolefin resin may be any one or more hydrogenated unsaturated polyolefin resins free of unsaturated carbon-carbon double bonds for the manufacture of prepreg, resin film, laminate, printed circuit board, or cured insulator. The hydrogenated unsaturated polyolefin resin may comprise at least one of hydrogenated styrene-butadiene copolymer, hydrogenated styrene-butadiene-styrene block polymer, hydrogenated styrene-isoprene copolymer, or a combination thereof, but the present invention is not limited thereto.

In some exemplary examples, the resin composition comprises maleimide triazine resin. The maleimide triazine resin may be any one or more maleimide triazine resins for the manufacture of prepreg, resin film, laminate, printed circuit board, or cured insulator. The maleimide triazine resin may be obtained by polymerizing the cyanate ester resin and the maleimide resin, particularly, may be obtained by polymerizing bisphenol A cyanate ester resin and maleimide resin, by polymerizing bisphenol F cyanate ester resin and maleimide resin, by polymerizing phenol novolac cyanate ester resin and maleimide resin, or by polymerizing dicyclopentadiene-containing cyanate ester resin and maleimide resin. The maleimide triazine resin may be obtained by polymerizing cyanate ester resin and maleimide resin in any molar ratio, particularly in a molar ratio of (1-10):1, particularly, (1-6):1, and more particularly, 1:1, 2:1, 4:1, or 6:1.

In some exemplary examples, the resin composition comprises small molecule vinyl-containing resin. The small molecule vinyl-containing resin may comprise a vinyl compound having a molecular weight less than or equal to 1000, particularly a molecular weight between 100 and 900, and more preferably a molecular weight between 100 and 800. The small molecule vinyl-containing resin may comprise styrene, divinylbenzene, ethylstyrene, bis(vinylbenzyl)ether, 1,2,4-trivinylcyclohexane (TVCH), bis(vinylphenyl)ethane (BVPE), bis(vinylphenyl)hexane, divinylphenyl dimethylene ether, divinylphenyl dimethylene benzene, triallyl isocyanurate (TAIC), triallyl cyanurate (TAC), or a combination thereof, but the present invention is not limited thereto.

In some exemplary examples, the resin composition comprises small molecule vinyl-containing resin prepolymer. The small molecule vinyl-containing resin prepolymer may comprise styrene prepolymer, divinylbenzene prepolymer, an ethylstyrene prepolymer, bis(vinylbenzyl)ether prepolymer, TVCH prepolymer, BVPE prepolymer, bis(vinylphenyl)hexane prepolymer, divinylphenyl dimethylene ether prepolymer, divinylphenyl dimethylene benzene prepolymer, TAlC prepolymer, TAC prepolymer, or a combination thereof, but the present invention is not limited thereto. For instance, the styrene prepolymer may represent a styrene content in the prepolymer of greater than or equal to 50 wt %, such as a styrene content in the styrene prepolymer of between 50 wt % and 99 wt %, and a second monomer unit content in the styrene prepolymer of less than or equal to 49 wt %, such as between 1 wt % and 49 wt %. For instance, in one exemplary example, the styrene prepolymer comprises 55 wt % to 75 wt % styrene monomer units, 15 wt % to 35 wt % divinylbenzene monomer units, and 5 wt % to 30 wt % ethylstyrene monomer units. In another exemplary example, the divinylbenzene prepolymer comprises 60 wt % divinylbenzene monomer units, 30 wt % ethylstyrene monomer units, and 10 wt % styrene monomer units. In another exemplary example, the ethylstyrene prepolymer comprises 60 wt % ethylstyrene monomer units, 30 wt % styrene monomer units, and 10 wt % divinylbenzene monomer units. For instance, the styrene prepolymer may also represent the styrene content in the prepolymer greater than or equal to the content of any other monomer. For instance, in one exemplary example, the styrene prepolymer comprises 40 wt % styrene monomer units, 30 wt % divinylbenzene monomer units, and 30 wt % ethylstyrene monomer units.

In some exemplary examples, the resin composition comprises styrene maleic anhydride resin. A molar ratio of styrene and maleic anhydride in the styrene maleic anhydride resin may be (1-8):1, such as 1:1, 2:1, 3:1, 4:1, 6:1, or 8:1. The styrene maleic anhydride resin may be a styrene maleic anhydride copolymer. The styrene maleic anhydride copolymer may be a styrene maleic anhydride copolymer available from Cray Valley Co., Ltd under trade names of SMA-1000, SMA-2000, SMA-3000, EF-30, EF-40, EF-60, EF-80, etc., or a styrene maleic anhydride copolymer sold by Polyscope under trade names of C400, C500, C700, C900, etc. but the present invention is not limited thereto. The styrene maleic anhydride resin may be an esterified styrene maleic anhydride copolymer. The esterified styrene maleic anhydride copolymer may be an esterified styrene maleic anhydride copolymer available from Cray Valley Co., Ltd under trade names of SMA1440, SMA17352, SMA2625, SMA3840, SMA31890, etc. but the present invention is not limited thereto. The resin composition may comprise one styrene maleic anhydride resin or a combination of a plurality of styrene maleic anhydride resins.

In some exemplary examples, the resin composition comprises phenol resin. The phenol resin may be monofunctional phenol resin, polyfunctional phenol resin, or a combination thereof, but the present invention is not limited thereto. The phenol resin may comprise phenoxy resin, novolac resin, or a combination thereof, but the present invention is not limited thereto.

In some exemplary examples, the resin composition comprises benzoxazine resin. The benzoxazine resin may comprise bisphenol A benzoxazine resin, bisphenol F benzoxazine resin, phenolphthalein benzoxazine resin, dicyclopentadiene benzoxazine resin, phosphorus-containing benzoxazine resin, diamine benzoxazine resin, and a vinyl/allyl-modified benzoxazine resin, or a combination thereof, but the present invention is not limited thereto. The benzoxazine resin is, for instance, produced by Huntsman undertrade names of LZ-8270 (phenolphthalein benzoxazine resin), LZ-8280 (bisphenol F benzoxazine resin), and LZ-8290 (bisphenol A benzoxazine resin), or produced by Showa Polymer Company under a trade name of HFB-2006M. The diamine benzoxazine resin may be a diaminodiphenyl methane benzoxazine resin, diaminodiphenyl ether benzoxazine resin, diaminodiphenyl sulfone benzoxazine resin, diaminodiphenyl thioether benzoxazine resin, or a combination thereof.

In some exemplary examples, the resin composition comprises cyanate ester resin. The cyanate ester resin may be various types of cyanate ester resins known in the art. The cyanate ester resin may comprise a cyanate ester resin having an Ar—O—C≡N structure (where Ar is an aromatic group, such as benzene, naphthalene, or anthracene), but the present invention is not limited thereto. The cyanate ester resin may comprise phenolic novolac cyanate ester resin, bisphenol A cyanate ester resin, bisphenol A novolac cyanate ester resin, bisphenol F cyanate ester resin, bisphenol F novolac cyanate ester resin, cyanate ester resin containing a dicyclopentadiene structure, cyanate ester resin containing a naphthalene ring structure, phenolphthalein cyanate ester resin, or a combination thereof, but the present invention is not limited thereto. The cyanate ester resin may comprise a cyanate ester resin produced by Lonza undertrade names of Primaset PT-15, PT-30S, PT-60S, BA-200, BA-230S, BA-3000S, BTP-2500, BTP-6020S, DT-4000, DT-7000, ULL 950S, HTL-300, CE-320, LVT-50, IeCy, etc. or a combination thereof, but the present invention is not limited thereto. Preferably, the resin composition does not comprise the cyanate ester resin. The cyanate ester resin has the risk of leaving bisphenol A harmful to health.

In some exemplary examples, the resin composition comprises polyester resin. The polyester resin is formed by esterifying an aromatic compound having a dicarboxylic acid group with an aromatic compound having a dihydroxy group. The polyester resin may be HPC-8000, HPC-8150, and HPC-8200 available from DIC Co., Ltd, or a combination thereof, but the present invention is not limited thereto.

In some exemplary examples, the resin composition comprises polyamide resin. The polyamide resin may be of various types known in the art and comprises various commercially available polyamide resin products, but the present invention is not limited thereto.

In some exemplary examples, the resin composition comprises polyimide resin. The polyimide resin may be of various types known in the art and comprises various commercially available polyimide resin products, but the present invention is not limited thereto.

In some exemplary examples, the resin composition further comprises at least one of an amine curing agent, a flame retardant, an inorganic filler, a curing accelerator, a polymerization inhibitor, a colorant, a solvent, a toughening agent, and a silane coupling agent.

In some exemplary examples, the resin composition comprises an amine curing agent. The amine curing agent may comprise dicyandiamide, diaminodiphenyl sulfone, diaminodiphenyl methane, diaminodiphenyl ether, diaminodiphenyl thioether, or a combination thereof, but the present invention is not limited thereto.

In some exemplary examples, the resin composition comprises a flame retardant. The flame retardant may be any one or more flame retardants for the manufacture of prepreg, resin film, laminate, printed circuit board, or cured insulator.

The flame retardant may be a phosphorus-containing flame retardant. The flame retardant may be ammonium polyphosphate, hydroquinone bis-(diphenylphosphate), bisphenol A bis-(diphenylphosphate), tri(2-carboxyethyl)phosphine (TCEP), tris(chloroisopropyl)phosphate, trimethyl phosphate (TMP), dimethyl methyl phosphonate (DMMP), resorcinol bis(dixylenyl phosphate) (RDXP, commercially available products such as PX-200, PX-201, and PX-202), phosphazene compounds (commercially available products such as SPB-100, SPH-100, and SPV-100), melamine polyphosphate, DOPO and derivatives or resins thereof, diphenylphosphine oxide (DPPO) and derivatives or resins thereof, melamine cyanurate, tri-hydroxy ethyl isocyanurate, aluminum hypophosphite (products such as OP-930 and OP-935), or a combination thereof, but the present invention is not limited thereto.

The flame retardant may be a DPPO compound (such as a bis-DPPO compound), a DOPO compound (such as a bis-DOPO compound), a DOPO resin (such as DOPO-HQ, DOPO-NQ, DOPO-PN, and DOPO-BPN), a DOPO-bonded epoxy resin, or a combination thereof, but the present invention is not limited thereto. DOPO-PN is a DOPO phenolic novolac compound, and DOPO-BPN may be a bisphenol novolac compound such as DOPO-bisphenol A novolac (DOPO-BPAN), DOPO-bisphenol F novolac (DOPO-BPFN), and DOPO-bisphenol S novolac (DOPO-BPSN).

In some exemplary examples, the resin composition comprises an inorganic filler. The inorganic filler may be any one or more inorganic fillers for the manufacture of prepreg, resin film, laminate, printed circuit board, or cured insulator. The inorganic filler may be silica (molten, non-molten, porous, or hollow), alumina, aluminum hydroxide, magnesium oxide, magnesium hydroxide, calcium carbonate, aluminum nitride, boron nitride, aluminum silicon carbide, silicon carbide, titanium dioxide, zinc oxide, zirconium oxide, mica, boehmite (AlOOH), calcined talc, talc, silicon nitride, calcined kaolin, or a combination thereof, but the present invention is not limited thereto. The inorganic filler may be in the form of spheres, fibers, plates, granules, flakes, or whiskers. The inorganic filler may be pre-treated with the silane coupling agent (particularly, an aminosilane coupling agent). The inorganic filler may be spherical silica having a surface treated with the aminosilane coupling agent.

The amount of the inorganic filler is not particularly limited. In some exemplary examples, the resin composition may comprise 100 parts by weight to 230 parts by weight of the inorganic filler, based on 100 parts by weight of a total solid resin (free of solvent and inorganic filler) in the resin composition. In some exemplary examples, a weight ratio of the maleimide resin to the inorganic filler may be 1:1.5 to 1:3.0.

In some exemplary examples, the resin composition comprises a curing accelerator. The curing accelerator may comprise catalysts, such as Lewis bases and Lewis acids. The Lewis base may comprise imidazole, boron trifluoride amine complex, ethyltriphenyl phosphonium chloride, 2-methylimidazole (2MI), 2-phenyl-1H-imidazole (2PZ), 2-ethyl-4-methylimidazole (2E4MI), triphenylphosphine (TPP), 4-dimethylaminopyridine (DMAP), or a combination thereof, but the present invention is not limited thereto. The Lewis acid may comprise metal salt compounds, such as manganese salt, iron salt, cobalt salt, nickel salt, copper salt, and zinc salt, particularly metal catalysts such as zinc octoate and cobalt octoate, but the present invention is not limited thereto. The curing accelerator may comprise a curing starter (i.e., initiator). The curing starter may comprise a peroxide that may generate radicals. The curing starter comprises 2,3-dimethyl-2,3-diphenylbutane, dicumyl peroxide, tert-butyl peroxybenzoate, tert-butyl peroxyisopropyl monocarbonate, dibenzoyl peroxide (BPO), 2,5-dimethyl-2,5-di(tert-butylperoxy)-3-hexyne (25B), bis(tert-butylperoxyisopropyl)benzene, azobisisobutylonitrile, or a combination thereof, but the present invention is not limited thereto.

In some exemplary examples, the resin composition comprises a polymerization inhibitor. The polymerization inhibitor may be of various types known in the art and comprises various commercially available polymerization inhibitor products, but the present invention is not limited thereto. The polymerization inhibitor may comprise 1,1-diphenyl-2-trinitrophenylhydrazine, methacrylonitrile, dithioester, nitroxide stable radical, triphenylmethyl radical, metal ion radical, sulfur radical, hydroquinone, p-methoxyphenol, p-benzoquinone, phenothiazine, 3-phenylnaphthylamine, p-tert-butylcatechol, methylene blue, 4,4′-butylidene bis(6-tert-butyl-3-methylphenol), 2,2′-methylene bis(4-ethyl-6-tert-butylphenol), or a combination thereof, but the present invention is not limited thereto. The polymerization inhibitor may comprise the nitroxide stable radical. The nitroxide stable radical may comprise a 2,2,6,6-tetrasubstituent piperidine-1-oxide radical, a 2,2,5,5-tetrasubstituent pyrrolidine-1-oxyl radical, or the like nitroxyl radical from cyclic hydroxylamine, or a combination thereof, but the present invention is not limited thereto. The “substituent” herein is, for instance, an alkyl group with a carbon number of less than 4, such as methyl, ethyl, propyl, and butyl, particularly methyl or ethyl. The nitroxide stable radical may be 2,2,6,6-tetramethylpiperidin-1-oxyl radical, 2,2,6,6-tetraethylpiperidin-1-oxyl radical, 2,2,6,6-tetramethyl-4-oxopiperidin-1-oxyl radical, 2,2,5,5-tetramethylpyrrolidine-1-oxyl radical, 1,1,3,3-tetramethylisoindoline-2-oxyl radical, N,N-di-tert-butylamine oxyl radical, or a combination thereof, but the present invention is not limited thereto. Stable radicals such as galvinoxyl radicals may also be used in place of nitroxyl radicals. The polymerization inhibitor may also be a product derived from the substitution of hydrogen atoms or atomic groups in the aforementioned polymerization inhibitor by other atoms or atomic groups, such as products derived from the substitution of hydrogen atoms in the polymerization inhibitor by atomic groups such as amino, hydroxyl, and ketone carbonyl.

In some exemplary examples, the resin composition comprises a colorant. The colorant may comprise a dye or a pigment, but the present invention is not limited thereto.

In some exemplary examples, the resin composition comprises a solvent. The addition of the solvent may change a solid content of the resin composition and may adjust the viscosity of the resin composition. The solvent may comprise methanol, ethanol, ethylene glycol monomethyl ether, acetone, butanone (also referred to as methyl ethyl ketone), methyl isobutyl ketone, cyclohexanone, toluene, xylene, methoxyethyl acetate, ethoxyethyl acetate, propoxyethyl acetate, ethyl acetate, dimethyl formamide, dimethyl acetamide, propylene glycol methyl ether, or a combination thereof, but the present invention is not limited thereto. The solvent added into the resin composition may be removed by volatilization during treatment of the resin composition into the prepreg or resin film. Therefore, an insulating layer of the prepreg or resin film contains no solvent or only a minor amount of solvent of less than or equal to 3 wt % (i.e., 3% by weight). Thus, the presence or absence of solvent in the resin composition does not affect the characteristics of the product.

In some exemplary examples, the resin composition comprises a toughening agent. The toughening agent may improve the toughness of the resin composition. The toughening agent may comprise carboxyl-terminated butadiene acrylonitrile rubber (CTBN), core-shell rubber, or a combination thereof, but the present invention is not limited thereto.

In some exemplary examples, the resin composition comprises a silane coupling agent. The silane coupling agent may comprise a silane compound. The silane compound comprises a siloxane compound, but the present invention is not limited thereto. The silane coupling agent may comprise an amino silane compound, an epoxide silane compound, a vinyl silane compound, an acrylate silane compound, a methacrylate silane compound, a hydroxyl silane compound, an isocyanate silane compound, a methacryloxy silane compound, an acryloxy silane compound, or a combination thereof, but the present invention is not limited thereto.

In one aspect, the present application provides a product of which at least a portion is made from the resin composition. The product, for instance, is a component suitable for use in various types of electronic products, and comprises a prepreg, a resin film, a laminate, a printed circuit board, or a cured insulator, but the present invention is not limited thereto. In one aspect, the present application provides a use of the resin composition of the present application in preparing a product. In one aspect, the present application provides the use of the resin composition of the present application in preparing the prepreg, the resin film, the laminate, the printed circuit board, or the cured insulator. In one aspect, the present application provides a product, comprising a resin layer made from the resin composition. In one aspect, the present application provides a method for preparing the product, comprising: providing the resin layer made from the resin composition.

The product may comprise the resin composition in a semi-cured state (B-stage) or a cured state (C-stage). The product may comprise a resin layer which is the resin composition in the semi-cured state or the cured state. The product may comprise the insulating layer that is the resin composition in the cured state.

In some exemplary examples, the present application provides a prepreg. The prepreg may comprise a reinforcing material and a semi-cured layer provided on the reinforcing material. The semi-cured layer is the resin composition in the semi-cured state. The semi-cured layer may be obtained by heating the resin composition to form the semi-cured state. In some exemplary examples, the present application provides a method for preparing the prepreg, comprising: providing the resin composition on the reinforcing material, and semi-curing the resin composition, particularly heating the resin composition to form the prepreg comprising the reinforcing material and the semi-cured layer. The providing the resin composition on the reinforcing material may comprise: coating the resin composition onto the reinforcing material. The heating may be baking heating. The heating may be heating to a semi-curing temperature. The semi-curing temperature may be between 100° C. and 200° C. The reinforcing material may be a fibrous material, a woven fabric, a non-woven fabric, or a combination thereof, and the present invention is not limited thereto. The woven fabric may comprise a fiberglass fabric. The fiberglass fabric may be commercially available fiberglass fabrics used for various printed circuit boards. The fiberglass fabric may be an E-type glass fabric, a D-type glass fabric, an S-type glass fabric, a T-type glass fabric, an L-type glass fabric, or a Q-type glass fabric. The type of fibers comprises yarns or rovings and the like, and the form may comprise splitting or non-splitting, but the present invention is not limited thereto. The woven fabric may comprise a liquid crystal resin woven fabric. The liquid crystal resin woven fabric may comprise a polyester woven fabric, a polyurethane woven fabric, or a combination thereof, and the present invention is not limited thereto. The non-woven fabric may comprise a liquid crystal resin non-woven fabric. The liquid crystal resin non-woven fabric may comprise a polyester non-woven fabric, a polyurethane non-woven fabric, or a combination thereof, and the present invention is not limited thereto. The reinforcing material may increase the mechanical strength of the prepreg. In some exemplary examples, the reinforcing material may also be pre-treated with the silane coupling agent.

In some exemplary examples, the present application provides a resin film. The resin film may comprise the resin composition in the semi-cured state. In one aspect, the present application provides a method for preparing the resin film, comprising: semi-curing the resin composition, particularly heating the resin composition. The method for preparing the resin film may further comprise: coating the resin composition onto a substrate. In some exemplary examples, the present application provides a resin film combination, comprising the substrate and the resin film provided on the substrate. In one aspect, the present application provides a method for preparing the resin film combination, comprising: providing the substrate and providing the resin film on the substrate. In some exemplary examples, the providing the resin film on the substrate comprises: coating the resin composition onto the substrate, and semi-curing the resin composition, particularly heating the resin composition. The substrate may be a polyethylene terephthalate film (PET film), a polyimide film (PI film), a copper foil, a resin-coated copper foil, or a combination thereof, but the present invention is not limited thereto. The heating may be, for instance, baking heating. The heating may be heating to a semi-curing temperature. The semi-curing temperature may be between 100° C. and 200° C.

In some exemplary examples, the present application provides a laminate. The laminate may comprise at least two pieces of metal foils and an insulating layer provided between these metal foils. In some exemplary examples, the insulating layer separates the metal foils. The metal foil may comprise copper, aluminum, nickel, platinum, silver, gold, or alloys thereof, and particularly may be a copper foil. The insulating layer may be obtained by heating and curing the aforementioned resin composition or the aforementioned resin composition in the semi-cured state. The heating may be, for instance, baking heating. The heat and curing may be heating to a curing temperature. The curing temperature may be between 180° C. and 250° C., particularly between 210° C. and 240° C. The time for curing may be 80 minutes to 180 minutes, particularly 100 minutes to 150 minutes. The curing may further comprise applying pressure to the semi-cured resin composition. The insulating layer may be formed from the aforementioned prepreg or resin film after curing (C-stage). For instance, the laminate may be a copper clad laminate (CCL).

The laminate may be further processed through a wiring process to form a circuit board, such as the printed circuit board. One way to manufacture the printed circuit board of the present application may be to use a double-sided copper clad laminate having a certain thickness, for instance 28-mil, and with a 0.5-ounce (oz) hyper very low profile (HVLP) copper foil (such as product EM-890, available from Elite Material), drilled and electroplated to provide electrical communication between a top copper foil and a bottom copper foil. The top copper foil and the bottom copper foil are then etched to form an inner circuit. The inner circuit is then browned and roughened to form a concave-convex structure on the surface to increase roughness. Then, the copper foil, the aforementioned prepreg, the aforementioned inner circuit board, the aforementioned prepreg, and the copper foil are sequentially stacked and heated at a temperature of 180° C. to 250° C. for 80 minutes to 180 minutes using a vacuum laminating apparatus to cure the insulating layer material of the prepreg. Later, various circuit board processes known in the art, such as blackening, drilling, and copper plating are performed on the copper foil at the outermost surface to obtain the printed circuit board.

In some exemplary examples, the present application provides a cured insulator. In some exemplary examples, the present application provides a method for preparing the cured insulator, comprising: curing the resin composition once or through multiple curing processes. The multiple curing refers to greater than or equal to two times of curing. For instance, the resin composition may be first semi-cured, particularly heating the resin composition to obtain the semi-cured resin composition. Then, the semi-cured resin composition is further cured, especially heating the semi-cured resin composition. The cured insulator may comprise the resin composition in the cured state, the resin composition in the cured state containing the reinforcing material, or a combination thereof. The heating may be, for instance, baking heating. In some exemplary examples, the semi-curing the resin composition is heating to a semi-curing temperature. The semi-curing temperature may be between 100° C. and 200° C. In some exemplary examples, the curing the resin composition once or curing the semi-cured resin composition is heating to a curing temperature. The curing temperature may be between 180° C. and 250° C., particularly between 210° C. and 240° C. The time for curing may be 80 minutes to 180 minutes, particularly 100 minutes to 150 minutes. The curing may further comprise applying pressure to the resin composition or the semi-cured resin composition.

The cured insulator may comprise the resin composition in the cured state. In some exemplary examples, the present application provides a method for preparing the cured insulator, comprising: curing the resin film, particularly heating the resin film. The method for preparing the cured insulator may further comprise: coating the resin composition onto the substrate, and/or semi-curing the resin composition to form the resin film.

The cured insulator may comprise the resin composition in the cured state containing the reinforcing material. In some exemplary examples, the present application provides a method for preparing the cured insulator, comprising: curing the prepreg, particularly heating the prepreg. The method for preparing the cured insulator may further comprise: providing the resin composition on the reinforcing material, and semi-curing the resin composition, particularly heating the resin composition to form the prepreg comprising the reinforcing material and the semi-cured layer.

The method for preparing the cured insulator may further comprise molding. For instance, the resin composition or the semi-cured resin composition may be put into a mold and shaped and cured in the mold at the curing temperature and a certain pressure, thereby obtaining a cured insulator of a particular shape.

The cured insulator may be an insulating layer with no metal on the surface of the aforementioned laminate or the printed circuit board after removing the surface metal foil.

In some exemplary examples, the products of the present application have at least one of the following characteristics:
a glass transition temperature greater than or equal to 325° C. as measured by a method described in IPC-TM-650 2.4.24.4;
a glass transition temperature greater than or equal to 260° C. as measured by a method described in IPC-TM-650 2.4.24.5;
a Z-axis ratio of thermal expansion less than or equal to 0.80% as measured by a method described in IPC-TM-650 2.4.24.5;
an inner resin flow after lamination of the product (such as an inner resin flow pattern) is greater than or equal to 8.0 mm;
a resin flow greater than or equal to 30% as measured by a method described in IPC-TM-650 2.3.17; and
the copper-free laminate has no edge stripe.

### Examples

The following examples are only used to illustrate the embodiments of the present invention and are not used to limit the present invention.

### Raw Materials

The chemical raw materials used in the following examples have the following structures and sources:
BMI-2300: phenylmethane maleimide oligomer, available from Daiwa Kasei Co., Ltd.
MIR-3000: biphenyl aralkyl bismaleimide, available from Nippon Kayaku Co., Ltd.
X9-470: indane structure-containing bismaleimide, available from DIC Co., Ltd.
BMI-5100: 3,3′-dimethyl-5,5′-diethyl-4,4′-diphenylmethane bismaleimide, available from Daiwa Kasei Co., Ltd.
BMI-4000: bisphenol A diphenyl ether bismaleimide, available from Daiwa Kasei Co., Ltd.
1,2-bis(diphenylphosphanyl)benzene: available from Aladdin.
2,2′-bis(diphenylphosphanyl)biphenyl: available from Aladdin.
2,2′-bis(diphenylphosphanyl)-1,1′-binaphthyl: available from Aladdin.
1,2-bis(diphenylphosphanyl)ethane: available from Aladdin.
TPP: triphenylphosphine, available from Aladdin.
2-PZ: diphenylimidazole, available from Shikoku Chemicals Corporation.
NC-3000H: biphenyl novolac epoxy resin, available from Nippon Kayaku Co., Ltd.
HP-7200H: DCPD epoxy resin, available from Nippon Kayaku Co., Ltd.
CNE200: o-cresol novolac epoxy resin, available from Changchun Chemical Co., Ltd.
NC-7000L: naphthol epoxy resin, available from Nippon Kayaku Co., Ltd.
Diallyl bisphenol A: available from Sichuan EM Technology Co., Ltd.
Diallyl bisphenol S: available from Shanghai Macklin Biochemical Technology Co., Ltd.
Bisphenol A bisallyl ether: available from Shanghai Macklin Biochemical Technology Co., Ltd.
SC-2050-SXJ: spherical silica having a surface treated with an aminosilane coupling agent, available from Admatechs Co., Ltd.
Butanone: commercially available from a variety of sources.
Cyclohexanone: commercially available from a variety of sources.

### Preparation of Resin Compositions

Resin compositions of examples E1 to E12 and comparative examples C1 to C9 of the present application are formulated according to the amounts in Table 1 and further fabricated into various types of test samples or products. The blank in the table indicates “0”. Table 1. Components of resin compositions of examples E1 to E12 and comparative examples C1 to C9 (unit: parts by weight)

| | | Examples | | | | | | | | | | | |
|---|---|---|---|---|---|---|---|---|---|---|---|---|---|
| Components | | E1 | E2 | E3 | E4 | E5 | E6 | E7 | E8 | E9 | E10 | E11 | E12 |
| Maleimide | BMI-2300 | 100 | 100 | 100 | | | 100 | 100 | 100 | 100 | 50 | 30 | 50 |
| resin | MIR-3000 | | | | 100 | | | | | | 30 | 50 | |
| | X9-470 | | | | | 100 | | | | | 20 | 20 | 40 |
| | BMI-5100 | | | | | | | | | | | | 5 |
| | BMI-4000 | | | | | | | | | | | | 5 |
| Organo- | 1,2-bis(diphenyl | 1 | 1 | 1 | 1 | 1 | 0.3 | 3 | 10 | | 0.5 | 1 | 1 |
| phosphine | phosphanyl)benzene | | | | | | | | | | | | |
| compound | 2,2′-bis(diphenyl | | | | | | | | | 1 | 0.5 | 1 | |
| | phosphanyl)biphenyl | | | | | | | | | | | | |
| Epoxy resin | NC-3000H | | 10 | 10 | 10 | 10 | 10 | 10 | 10 | 10 | 30 | 5 | |
| | HP-7200H | | | | | | | | | | | | 5 |
| | CNE200 | | | | | | | | | | | | 5 |
| | NC-7000L | | | | | | | | | | | | 2 |
| Diallyl | Diallyl bisphenol A | | | 10 | 10 | 10 | 10 | 10 | 10 | 10 | 5 | 20 | |
| bisphenol | Diallyl bisphenol S | | | | | | | | | | | | 5 |
| resin | Bisphenol A bisallyl ether | | | | | | | | | | | | 5 |
| Inorganic | SC-2050-SXJ | Z*1.5 | Z*1.5 | Z*1.5 | Z*1.5 | Z*1.5 | Z*1.5 | Z*1.5 | Z*1.5 | Z*1.5 | Z*1.0 | Z*2.3 | Z*1.8 |
| filler | | | | | | | | | | | | | |
| Solvent | Butanone | q.s. | q.s. | q.s. | q.s. | q.s. | q.s. | q.s. | q.s. | q.s. | q.s. | q.s. | q.s. |
| | Cyclohexanone | q.s. | q.s. | q.s. | q.s. | q.s. | q.s. | q.s. | q.s. | q.s. | q.s. | q.s. | q.s. |

| | | Comparative examples | | | | | | | | |
|---|---|---|---|---|---|---|---|---|---|---|
| Components | | C1 | C2 | C3 | C4 | C5 | C6 | C7 | C8 | C9 |
| Maleimide resin | BMI-2300 | 100 | 100 | 100 | 100 | 100 | 100 | 100 | 100 | 100 |
| Organophosphine | 1,2-bis(diphenyl | | | | | 15 | | | | |
| compound | phosphanyl)benzene | | | | | | | | | |
| | 2,2′-bis(diphenylphosphanyl)- | | | | | | 1 | | | 1 |
| | 1,1′-binaphthyl | | | | | | | | | |
| | 1,2-bis(diphenyl | 1 | | | | | | | 1 | |
| | phosphanyl)ethane | | | | | | | | | |
| | TPP | | 1 | | | | | 1 | | |
| | 2-PZ | | | 1 | | | | | | |
| Epoxy resin | NC-3000H | 10 | 10 | 10 | 10 | 10 | 10 | | | |
| Diallyl bisphenol | Diallyl bisphenol A | 10 | 10 | 10 | 10 | 10 | 10 | | | |
| resin | | | | | | | | | | |
| Inorganic filler | SC-2050-SXJ | Z*1.5 | Z*1.5 | Z*1.5 | Z*1.5 | Z*1.5 | Z*1.5 | Z*1.5 | Z*1.5 | Z*1.5 |
| Solvent | Butanone | q.s. | q.s. | q.s. | q.s. | q.s. | q.s. | q.s. | q.s. | q.s. |
| | Cyclohexanone | q.s. | q.s. | q.s. | q.s. | q.s. | q.s. | q.s. | q.s. | q.s. |

“Z” in Table 1 represents a total amount of all other components excluding (i.e., not including) the inorganic filler and the solvent in the resin composition of each example or comparative example. In the table, “Z*1.0” represents that an addition amount of the inorganic filler is 1.0 times the aforementioned Z. For instance, “Z*1.5” in example E1 represents that the addition amount of the inorganic filler is 151.5 parts by weight (101 parts by weight multiplied by 1.5).

The addition amount of butanone and cyclohexanone in Table 1 being “q.s.” represents The amount of the solvent when the solvent is added in such a way that the solid resin (such as maleimide resin) in the resin composition may be completely dissolved. For the resin composition using both butanone and cyclohexanone, “q.s.” represents a total amount of the two solvents making the overall solid content of the resin composition being an ideal solid content, such as 70% by weight, but the present invention is not limited thereto.

The methods for preparing the resin compositions of examples E1 to E12 and comparative examples C1 to C9 are as follows.

### Preparation of Varnish

Components of examples E1 to E12 or comparative examples C1 to C9 were added into a stirring tank according to the amounts in Table 1 for stirring and uniformly mixed to form a resin composition referred to as a resin varnish.

Taking example E1 as an example, 100 parts by weight of the maleimide resin BMI-2300 were added into a stirrer containing appropriate amounts of butanone and cyclohexanone and stirred until the solid components are completely dissolved. Then “Z*1.5” parts by weight of spherical silica SC-2050-SXJ (i.e., 151.5 parts by weight) were added and stirred until completely dispersed, and then 1 part by weight of 1,2-bis(diphenylphosphanyl)benzene (dissolved as a solution using an appropriate amount of solvent in advance) was added and stirred for 1 hour to obtain a varnish of the resin composition E1.

In addition, the varnishes of the other examples E2 to E12 and comparative examples C1 to C9 were prepared referring to the method for preparing the varnish of example E1 according to the amounts of the components listed in Table 1.

### Preparation of Prepreg-1 (by 2116 E-Fiberglass Fabric)

The varnishes of the resin compositions of examples E1 to E12 and comparative examples C1 to C9 were placed in an impregnation tank in batches. A fiberglass fabric (such as E-fiberglass fabric having a specification of 2116) was passed through the above-mentioned impregnation tank so that the resin composition was attached to the fiberglass fabric and heated to a semi-cured state (B-Stage) at 150° C. to obtain the prepreg-1 (resin content about 52%).

### Preparation of Prepreg-2 (by 1080 E-Fiberglass Fabric)

The varnishes of the resin compositions of examples E1 to E12 and comparative examples C1 to C9 were placed in an impregnation tank in batches. A fiberglass fabric (such as E-fiberglass fabric having a specification of 1080) was passed through the above-mentioned impregnation tank so that the resin composition was attached to the fiberglass fabric and heated to a semi-cured state (B-Stage) at 150° C. to obtain the prepreg-2 (resin content about 70%).

### Preparation of Copper Clad Laminate-1 (Formed by Laminating Eight Prepreg-1)

Two reverse treat foil copper foils (RTF copper foils) having a thickness of 12 μm and eight prepreg-1 prepared from the resin compositions were prepared in batches. The copper clad laminate-1 was formed by laminating in an order of a copper foil/eight prepreg-1/a copper foil under vacuum conditions at 230° C. for 120 minutes. The eight laminated prepreg-1 were cured (C-stage) to form an insulating layer between two copper foils, and the resin content of the insulating layer was about 52%.

### Preparation of Copper-Free Laminate-1 (Formed by Laminating Eight Prepreg-1)

The above-mentioned copper clad laminate-1 was etched to remove copper foils on two sides to obtain the copper-free laminate-1, which was formed by laminating eight prepreg-1 and had a resin content of about 52%.

### Test and Characteristic Analysis of Products

### 1. Glass Transition Temperature (Tg) Test

The “copper-free laminate-1” prepared from the resin compositions of the aforementioned examples or comparative examples were used as samples to be tested for dynamic mechanical analysis (DMA). The samples were heated at a temperature rise rate of 2° C. per minute in a temperature range from 35° C. to 400° C., and the glass transition temperature (in ° C.) of each sample to be tested was measured by a method described in IPC-TM-650 2.4.24.4.

The “copper-free laminate-1” prepared from the resin compositions of the aforementioned examples or comparative examples were also used as samples to be tested for thermal mechanical analysis (TMA). The samples were heated at a temperature rise rate of 10° C. per minute in a temperature range from 35° C. to 350° C., and the glass transition temperature (in ° C.) of each sample to be tested was measured by a method described in IPC-TM-650 2.4.24.5.

In the art, the higher the glass transition temperature, the better. A difference in glass transition temperature being greater than or equal to 5° C. represents a significant difference (significant technical difficulty) in glass transition temperature between different laminates.

For instance, the product made from the resin composition disclosed in the present application has a DMA-Tg measured by the method described in IPC-TM-650 2.4.24.4 greater than or equal to 325° C., such as between 325° C. and 392° C.; and a TMA-Tg measured by the method described in IPC-TM-650 2.4.24.5 greater than or equal to 260° C., such as greater than or equal to 262° C. or between 262° C. and 295° C.

### 2. Ratio of Thermal Expansion (or Ratio of Dimensional Change)

The “copper-free laminate-1” prepared from the resin compositions of the aforementioned examples or comparative examples were used as samples to be tested for TMA. The samples were heated at a temperature rise rate of 10° C. per minute in a temperature range from 35° C. to 265° C., and a Z-axis ratio of dimensional change (a temperature range from 50° C. to 260° C., in %) of each sample to be tested was measured by the method described in IPC-TM-650 2.4.24.5.

In the art, the lower the measured ratio of dimensional change, the better. When the ratio of thermal expansion is less than or equal to 1.2%, the difference in the ratios of thermal expansion being greater than or equal to 0.05% represents a significant difference (significant technical difficulty).

A large ratio of dimensional change represents a high Z-axis ratio of thermal expansion of the laminate. For copper clad laminates, a high ratio of thermal expansion tends to cause the printed circuit board prepared thereby to be prone to problems such as a decrease in yield due to displacement at a line contact (such as a blind hole or a buried hole, but the present invention is not limited thereto) or a decrease in reliability due to a delamination during processing.

For instance, the product made from the resin composition disclosed in the present application has a Z-axis ratio of thermal expansion less than or equal to 0.80%, such as less than or equal to 0.79% or between 0.35% and 0.79%, as measured by the method described in IPC-TM-650 2.4.24.5.

### 3. Inner Resin Flow

A copper-containing laminate of EM-827 was first prepared as a copper-containing core (commercially available from Elite Electronic Material (Zhongshan) Co., Ltd, using 7628 E-fiberglass fabric and 1 oz. HTE copper foil) having a thickness of 28 mil. The surface copper foil of the copper-containing core was subjected to a known browning treatment process to obtain a browned core. The aforementioned browned core was prepared having a thickness of 28 mil and a length and width of 18 inches and 16 inches, respectively.

The “prepreg-2” prepared from the resin composition of each of the aforementioned examples or comparative examples was then prepared, and a diamond-shaped opening having a length and a width of 4 inches was punched in the center of the prepreg-2 using a known punching machine.

A copper-containing multilayer board was prepared by sequentially laminating one 0.5 oz. HTE copper foil (reverse-laminated, i.e., with a shiny side of the copper foil contacting the prepreg), one prepreg-2 (with the aforementioned diamond-shaped opening), and one browned core, followed by laminating and curing under vacuum, high temperature (200° C.), and high pressure (360 psi) conditions for 2 hours.

The reverse-laminated copper foil on the surface of the copper-containing multilayer board was removed to obtain an inner resin flow pattern.

The inner resin flow pattern was taken, and each diamond-shaped side of 4 inches×4 inches was used as a baseline, each side was divided into 4 equal parts by 3 equally divided points, and the resin flow at each of the 12 points (i.e., a resin flowing distance in a vertical direction at each of the 12 points) was measured, and then an average value of the resin flows at the 12 points was calculated to obtain the inner resin flow (average value), in the unit of millimeter (hereinafter abbreviated as mm).

In the art, the greater the measured inner resin flow, the better the fluidity of the prepreg. A difference in the inner resin flow being greater than or equal to 1.0 mm represents a significant difference (significant technical difficulty).

In general, the inner resin flow is preferably between 6.0 mm and 20.0 mm, more preferably between 8.0 mm and 18.0 mm. The inner resin flow being less than 6.0 mm represents an insufficient resin flow. When the subsequent prepreg is used for adding layers, it may occur that the holes cannot be filled effectively, which may easily cause resin insufficiency or delamination on the circuit board.

### 4. Resin Flow (RF)

The “prepreg-2” prepared from the resin composition of each of the aforementioned examples or comparative examples was selected as a sample to be tested and cut into four diamonds of 4 inches×4 inches using a known punching machine.

The resin flow (in %) of each sample to be tested was measured by a method described in IPC-TM-650 2.3.17.

In the art, the greater the measured resin flow, the better the fluidity of the prepreg. A difference in the resin flows being greater than or equal to 1% represents a significant difference (significant technical difficulty). For the prepreg of this specification, the resin flow is preferably between 30% and 40%.

5. Laminate Edge Stripe (a.k.a. Dendritic Stripe, or Branch-Like Pattern)

The “copper-free laminate-1” prepared from the resin composition of each of the aforementioned examples or comparative examples was prepared, and a surface condition of an insulating layer of the copper-free laminate-1 was determined by visual observation by a person. The dendritic distribution on the edge represented a non-uniform phenomenon caused by poor compatibility or large fluidity difference of the components in the resin composition.

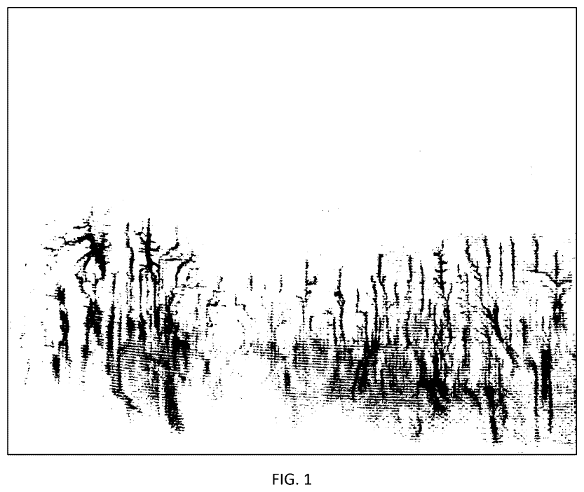

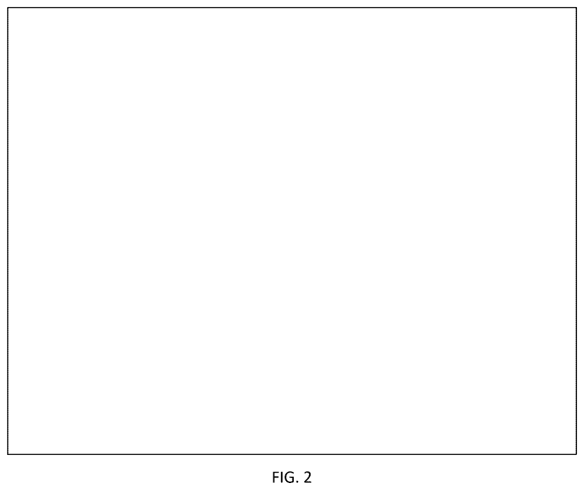

An appearance schematic diagram of a copper-free laminate with a distribution of dendritic stripes is shown in FIG. 1. The more the number of dendritic stripes represents the more serious the non-uniform phenomenon. An appearance schematic diagram of a normal copper-free laminate without the distribution of dendritic stripes is shown in FIG. 2.

Areas of the laminate with the dendritic distribution may result in non-uniform characteristics (poor reliability) of the subsequently produced printed circuit board, such as poor dielectric properties, low heat resistance, non-uniform thermal expansion or interlayer deterioration. Therefore, the laminate with the dendritic distribution must be directly scrapped, resulting in a large decrease in yield.

Testing and characteristic analysis results of the DMA-Tg obtained by DMA, DMA-Tg obtained by TMA, ratio of thermal expansion (temperature range of 50° C.-260° C.), inner resin flow, resin flow, laminate edge stripe of the products prepared using the resin compositions of various examples and comparative examples of the present application are shown in Table 2. Table 2 Testing and characteristic analysis results of resin composition products of various examples and comparative examples of present application

| Property test | Unit | E1 | E2 | E3 | E4 | E5 | E6 | E7 | E8 | E9 | E10 | E11 | E12 |
|---|---|---|---|---|---|---|---|---|---|---|---|---|---|
| DMA-Tg | ° C. | 392 | 389 | 375 | 340 | 345 | 370 | 376 | 372 | 377 | 330 | 325 | 372 |
| TMA-Tg | ° C. | 295 | 292 | 288 | 270 | 271 | 282 | 288 | 282 | 286 | 265 | 262 | 280 |
| Ratio of thermal | % | 0.35 | 0.40 | 0.53 | 0.60 | 0.56 | 0.57 | 0.51 | 0.55 | 0.56 | 0.78 | 0.79 | 0.60 |
| expansion | | | | | | | | | | | | | |
| Inner resin flow | mm | 12.0 | 13.0 | 15.0 | 12.0 | 14.0 | 18.0 | 11.0 | 8.5 | 16.0 | 18.0 | 10.0 | 15.0 |
| Resin flow | % | 32 | 33 | 35 | 32 | 35 | 40 | 31 | 30 | 36 | 39 | 31 | 35 |
| Laminate edge | | None | None | None | None | None | None | None | None | None | None | None | None |
| stripe | | | | | | | | | | | | | |

| Property test | Unit | C1 | C2 | C3 | C4 | C5 | C6 | C7 | C8 | C9 |
|---|---|---|---|---|---|---|---|---|---|---|
| DMA-Tg | ° C. | 370 | 365 | 367 | 310 | 360 | 315 | 385 | 375 | 320 |
| TMA-Tg | ° C. | 285 | 280 | 381 | 240 | 277 | 246 | 292 | 289 | 252 |
| Ratio of thermal | % | 0.60 | 0.70 | 0.68 | 1.20 | 0.65 | 0.90 | 0.46 | 0.56 | 0.85 |
| expansion | | | | | | | | | | |
| Inner resin flow | mm | 5.0 | 3.0 | 2.0 | >20.0 | 4.0 | >20.0 | 2.0 | 4.0 | 20.0 |
| Resin flow | % | 25 | 22 | 15 | 45 | 23 | 45 | 15 | 23 | 42 |
| Laminate edge | | None | None | Serious | Serious | None | Serious | None | None | Serious |
| stripe | | | | stripe | stripe | | stripe | | | stripe |

According to the test results of Table 2, the following phenomena may be observed.

By comparing example E1 with comparative examples C7-C9, it may be confirmed that the products prepared in the present application can simultaneously achieve at least one of the technical effects of characteristics of increasing the glass transition temperature, reducing the ratio of thermal expansion, increasing the inner resin flow, increasing the resin flow, and having no edge stripe of the laminate using the maleimide resin and the organophosphine compound within the scope of the present application, compared with the organophosphine compound of which the type is outside the scope.

By comparing examples E3 and E6-E8 with comparative examples C4-C5, it may be confirmed that the products prepared in the present application can simultaneously achieve at least one of characteristics of increasing the glass transition temperature, reducing the ratio of thermal expansion, increasing the inner resin flow, increasing the resin flow, and having no edge stripe of the laminate using 100 parts by weight of the maleimide resin and 0.3 parts by weight to 10.0 parts by weight of the organophosphine compound in the present application, compared with the resin composition in an amount outside the scope.

By comparing examples E1-E12 with comparative examples C1-C9, it may be confirmed that the technical effects of having an inner resin flow of greater than or equal to 8.0 mm, a resin flow of greater than or equal to 30%, and no edge stripe of the laminate may be simultaneously achieved using 100 parts by weight of the maleimide resin in combination with 0.3 parts by weight to 10.0 parts by weight of the organophosphine compound in the present application. On the contrary, the aforementioned technical effects cannot be simultaneously achieved by the comparative examples C1-C9 without using the technical solution of the present application.

What is claimed is:

1. A resin composition, comprising:
100 parts by weight of a maleimide resin; and
0.3 parts by weight to 10.0 parts by weight of an organophosphine compound,
wherein the organophosphine compound has a structure shown in Formula (1), and 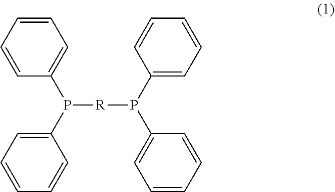
wherein —R— comprises a substituted or unsubstituted phenylene group, biphenylene group, or naphthylene group.

2. The resin composition according to claim 1, wherein the organophosphine compound comprises 1,2-bis(diphenylphosphanyl)benzene, 2,2′-bis(diphenylphosphanyl)biphenyl, 1,8-bis(diphenylphosphanyl)naphthalene, or a combination thereof.

3. The resin composition according to claim 1, wherein the maleimide resin comprises 4,4′-diphenylmethane bismaleimide, phenylmethane maleimide oligomer, biphenyl aralkyl bismaleimide, indane structure-containing bismaleimide, m-phenylene bismaleimide, bisphenol A diphenyl ether bismaleimide, 3,3′-dimethyl-5,5′-diethyl-4,4′-diphenylmethane bismaleimide, 4-methyl-1,3-phenylene bismaleimide, 1,6-bismaleimide-(2,2,4-trimethyl)hexane, 2,3-dimethylbenzene maleimide, 2,6-dimethylbenzene maleimide, N-phenylmaleimide, maleimide resin containing an aliphatic long chain structure, or a combination thereof.

4. The resin composition according to claim 1, wherein the resin composition further comprises an epoxy resin.

5. The resin composition according to claim 4, wherein the epoxy resin comprises bisphenol A epoxy resin, bisphenol F epoxy resin, bisphenol S epoxy resin, bisphenol AD epoxy resin, novolac epoxy resin, trifunctional epoxy resin, tetrafunctional epoxy resin, dicyclopentadiene (DCPD) epoxy resin, phosphorus-containing epoxy resin, p-xylene epoxy resin, naphthalene epoxy resin, benzofuran epoxy resin, isocyanate-modified epoxy resin, or a combination thereof.

6. The resin composition according to claim 4, wherein the resin composition comprises 5 parts by weight to 30 parts by weight of the epoxy resin.

7. The resin composition according to claim 4, further comprising a diallyl bisphenol resin, wherein the diallyl bisphenol resin comprises a compound shown in Formula (5) or Formula (6), or a combination thereof: 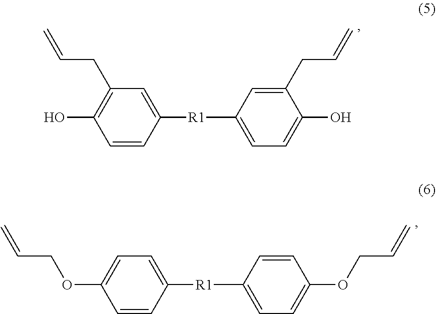
wherein, R1 is —C(CH₃)₂—, —CH₂—, or —SO₂—.

8. The resin composition according to claim 7, wherein the resin composition comprises 5 parts by weight to 20 parts by weight of the diallyl bisphenol resin.

9. The resin composition according to claim 1, wherein the resin composition further comprises polyolefin resin, maleimide triazine resin, small molecule vinyl-containing resin, small molecule vinyl-containing resin prepolymer, styrene maleic anhydride resin, phenol resin, benzoxazine resin, cyanate ester resin, polyester resin, polyamide resin, polyimide resin, or a combination thereof.

10. The resin composition according to claim 1, wherein the resin composition does not comprise cyanate ester resin.

11. The resin composition according to claim 1, wherein the resin composition further comprises an amine curing agent, a flame retardant, an inorganic filler, a curing accelerator, a polymerization inhibitor, a colorant, a solvent, a toughening agent, a silane coupling agent, or a combination thereof.

12. The resin composition according to claim 11, wherein a weight ratio of the maleimide resin to the inorganic filler is 1:1.5 to 1:3.0.

13. A product, comprising a prepreg, a resin film, a laminate, a printed circuit board, or a cured insulator, wherein at least a portion of the product is made from the resin composition according to claim 1.

14. The product according to claim 13, wherein the product has a glass transition temperature greater than or equal to 325° C. as measured by a method described in IPC-TM-650 2.4.24.4.

15. The product according to claim 13, wherein the product has a glass transition temperature greater than or equal to 260° C. as measured by a method described in IPC-TM-650 2.4.24.5.

16. The product according to claim 13, wherein the product has a Z-axis ratio of thermal expansion less than or equal to 0.80% as measured by a method described in IPC-TM-650 2.4.24.5.

17. The product according to claim 13, wherein an inner resin flow after lamination of the product is greater than or equal to 8.0 mm.

18. The product according to claim 13, wherein the product has a resin flow greater than or equal to 30% as measured by a method described in IPC-TM-650 2.3.17.

19. The product according to claim 13, wherein a copper-free laminate of the product has no edge stripe.
